(19) United States
(12) Patent Application Publication
(10) Pub. No.: US 2020/0136075 A1
(43) Pub. Date: Apr. 30, 2020

(54) LIGHT-EMITTING LAYER, LIGHT-EMITTING DEVICE, AND LIGHT-EMITTING LAYER MANUFACTURING APPARATUS

(71) Applicant: SHARP KABUSHIKI KAISHA, Sakai City, Osaka (JP)

(72) Inventors: MASAYUKI KANEHIRO, Sakai City, Osaka (JP); TAKESHI ISHIDA, Sakai City, Osaka (JP); YOUHEI NAKANISHI, Sakai City, Osaka (JP); SHOTA OKAMOTO, Sakai City, Osaka (JP)

(21) Appl. No.: 16/624,884

(22) PCT Filed: Jun. 15, 2018
(86) PCT No.: PCT/JP2018/022837

§ 371 Date: Dec. 19, 2019

(30) Foreign Application Priority Data
Jun. 22, 2017 (JP) 2017-122611

(51) Int. Cl. H01L 51/50; H01L 51/00; H01L 51/52; H01L 51/56

(52) U.S. Cl. CPC H01L 51/502; H01L 51/0018; H01L 51/56; H01L 51/5221; H01L 51/5206

(57) ABSTRACT

With the purpose of providing a light-emitting layer that is suitable for mass production and a light-emitting device having the light-emitting layer, without including a high-temperature process, there is provided a light-emitting device having: a light-emitting layer formed of a photosensitive material, in which quantum dots are dispersed; a first electrode of a lower layer than the light-emitting layer; and a second electrode of a higher layer than the light-emitting layer.

### TECHNICAL FIELD

The present invention relates to a light-emitting layer provided with quantum dots, a light-emitting element provided with the light-emitting layer, and a light-emitting device provided with the light-emitting element.

### BACKGROUND ART

PTL 1 discloses a method for forming or patterning a nanostructure array. PTL 2 discloses a method for patterning a quantum dot layer onto an element substrate.

### CITATION LIST

### Patent Literature

PTL 1: Japanese Unexamined Patent Application Publication “Japanese Translation of PCT International Application Publication No. 2009-545883 (published on Dec. 24, 2009)”

PTL 2: Japanese Unexamined Patent Application Publication, “Japanese Unexamined Patent Application Publication No. 2013-56412 (published on 28 Mar. 2013)”

### SUMMARY OF INVENTION

### Technical Problem

The method described in PTL 1 includes a high temperature process that may deactivate the light-emitting performance of quantum dots, and it is difficult for this method to be applied to a light-emitting device that is provided with quantum dots. Furthermore, in the method described in PTL 2, it is difficult to increase the size and increase the resolution of a light-emitting device and the takt time is long, and therefore the method described in PTL 2 is not suitable for a mass production process.

The present invention takes the aforementioned problems into consideration, and the purpose thereof is to facilitate the coating of different light emission colors, in a light-emitting device provided with quantum dots in a light-emitting layer.

### Solution to Problem

In order to solve the aforementioned problems, a light-emitting layer according to an aspect of the present invention is formed of a photosensitive material in which quantum dots are dispersed.

Furthermore, in order to solve the aforementioned problems, a light-emitting layer manufacturing apparatus according to an aspect of the present invention carries out: application of a photosensitive material in which quantum dots are dispersed, onto a base material; formation of an exposed region and an unexposed region in the photosensitive material on the base material; and removal of the photosensitive material in at least a portion of the exposed region or at least a portion of the unexposed region.

### Advantageous Effects of Invention

According to an aspect of the present invention, it is possible to provide a light-emitting layer provided with quantum dots, which facilitates an increase in size and an increase in resolution and with which it is possible to shorten the takt time, without deactivating the light-emitting performance of the quantum dots.

### BRIEF DESCRIPTION OF DRAWINGS

FIG. 1 is a cross-sectional view of steps depicting an example of a manufacturing method for a light-emitting device according to embodiment 1 of the present invention.

FIG. 2 is a top view and a cross-sectional view of the light-emitting device according to embodiment 1 of the present invention.

FIG. 3 is a flowchart depicting an example of the manufacturing method for the light-emitting device according to embodiment 1 of the present invention.

FIG. 4 is a block diagram depicting a manufacturing apparatus used for manufacturing light-emitting layers of the light-emitting device according to embodiment 1 of the present invention.

FIG. 5 is a cross-sectional view depicting the light emission mechanism of the light-emitting device according to embodiment 1 of the present invention.

FIG. 6 is a cross-sectional view of steps depicting an example of a manufacturing method for a light-emitting device according to embodiment 2 of the present invention.

FIG. 7 is a cross-sectional view of a light-emitting device according to embodiment 3 of the present invention.

FIG. 8 is a flowchart depicting an example of a manufacturing method for the light-emitting device according to embodiment 3 of the present invention.

FIG. 9 is a cross-sectional view depicting the light emission mechanism of the light-emitting device according to embodiment 3 of the present invention.

FIG. 10 is a cross-sectional view of a light-emitting device according to embodiment 4 of the present invention.

FIG. 11 is a cross-sectional view depicting the light emission mechanism of the light-emitting device according to embodiment 4 of the present invention.

### DESCRIPTION OF EMBODIMENTS

### Embodiment 1

In the present specification, the direction from a light-emitting layer of a light-emitting device toward a first electrode is referred to as the “downward direction”, and the direction from the light-emitting layer of the light-emitting device toward a second electrode is referred to as the “upward direction”.

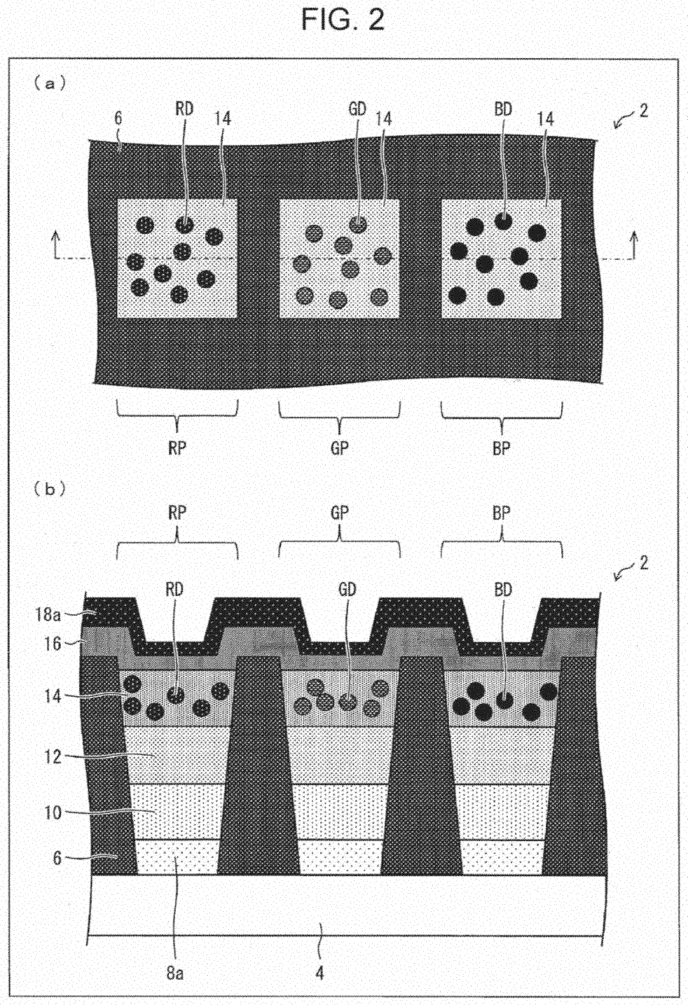

FIG. 2 is an enlarged top view and an enlarged cross-sectional view of a light-emitting device 2 according to the present embodiment. FIG. 2(a) is a drawing depicting an upper surface in the periphery of pixels of the light-emitting device 2, through an electron transport layer 16 and a second electrode 18a. FIG. 2(b) is a cross-sectional view along the arrow in FIG. 2(a).

As depicted in FIG. 2(b), the light-emitting device 2 is a structure in which layers are laminated on an array substrate 4 on which undepicted TFTs (thin film transistors) are formed. first electrodes 8a are electrically connected to the TFTs and are provided with edge covers 6 for preventing short circuiting between electrodes. Positive hole injection layers 10, positive hole transport layers 12, light-emitting layers 14, the electron transport layer 16, and the second electrode 18a are provided on the first electrodes 8a. As depicted in FIG. 2, the regions surrounded by the edge covers 6 are pixel regions for each color, and a red pixel region RP, a green pixel region GP, and a blue pixel region BP are provided.

The positive hole injection layers 10, the positive hole transport layers 12, and the light-emitting layers 14 are formed in this order from the downward side as layers above the first electrodes 8a on the array substrate 4. The array substrate 4 is a transparent substrate on which the TFTs are formed corresponding to each of the first electrodes 8a serving as pixels. Glass or a bendable plastic may be used as a material for the substrate. A flexible light-emitting device 2 can be obtained in the case where plastic is used as the array substrate 4.

As a material for the TFTs, there are amorphous Si-based semiconductors, low-temperature polycrystalline Si-based semiconductors, oxide semiconductors, and the like, and an oxide semiconductor is preferably used. An oxide semiconductor has greater mobility and less variation in performance than amorphous Si. Therefore, TFTs provided with oxide semiconductors are preferable for a next generation display device having a higher resolution.

Furthermore, oxide semiconductors are formed by means of a process that is simpler than that for low-temperature polycrystalline Si. Therefore, TFTs provided with oxide semiconductors have the benefit of being able to be applied also to apparatuses that require a large area.

Possible examples of an oxide semiconductor include a compound (In—Ga—Zn—O) consisting of indium (In), gallium (Ga), zinc (Zn), and oxygen (O), a compound (In-Tin-Zn—O) consisting of indium (In), tin (Tin), zinc (Zn), and oxygen (O), a compound (In—Al—Zn—O) consisting of indium (In), aluminum (Al), zinc (Zn), and oxygen (O), or the like.

The first electrodes 8a are anodes and have light-transmitting properties. The first electrodes 8a may include a transparent oxide such as ITO, IZO, or ISO, for example. The positive hole injection layers 10 may include PEDOT/PSS, and a possible example is Clevios (registered trademark) AI4083. The positive hole transport layers 12 may include an organic material such as PVK, poly-TPD, CBP, NPD, or TFB. Moreover, the positive hole transport layers 12 may include an inorganic material such as NiO or MoO₃.

The electron transport layer 16 and the second electrode 18a are formed in this order from the downward side on the upper surfaces of the light-emitting layers 14. ZnO nanoparticles are generally used as the electron transport layer 16. Furthermore, the electron transport layer 16 may include Alq3, PBD, TPBi, BCP, Balq, CDBP, or the like. The second electrode 18a is a cathode and has light-reflecting properties. The second electrode 18a may include Mg, Ca, Na, Ti, In, Ir, Li, Gd, Al, Ag, Zn, Pb, Ce, Ba, LiF/Al, LiO₂/Al, LiF/Ca, BaF₂/Ca, or the like. It should be noted that an electron injection layer may be formed between the electron transport layer 16 and the second electrode 18a.

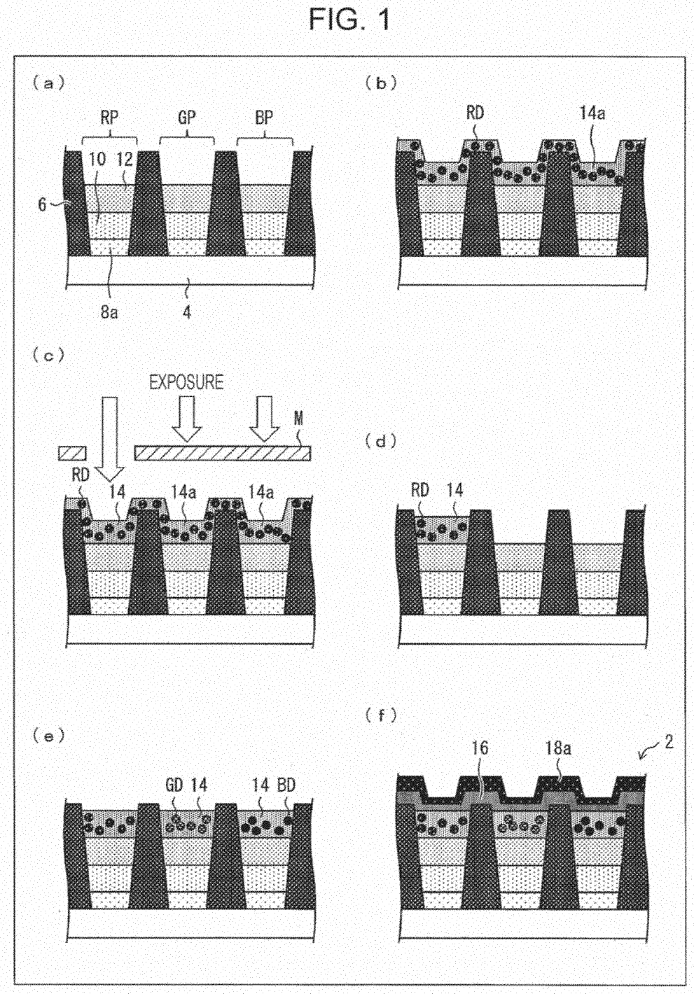

Here, the light-emitting layers 14 have quantum dots (semiconductor nanoparticles). The quantum dots are dispersed within the light-emitting layers 14. The quantum dots in a light-emitting layer provided in a portion of the plurality of pixel regions are different from the quantum dots in the light-emitting layers provided in the other different pixel regions. For example, as depicted in FIG. 1(a), the light-emitting layers 14 formed in each of the pixel regions RP, GP, and BP respectively have the three types of quantum dots of red quantum dots RD, green quantum dots GD, and blue quantum dots BD.

The quantum dots RD, GD, and BD each have different wavelength bands for emitted fluorescence, and respectively emit red, green, and blue as fluorescence. The light-emitting layers 14 may be provided with quantum dots that emit yellow as fluorescence, for example, as well as the quantum dots RD, GD, and BD. The quantum dots RD, GD, and BD may have a core-shell structure, and, for example, may include CdSe/ZnSe, CdSe/ZnS, CdS/ZnSe, CdS/ZnS, ZnSe/ZnS, InP/ZnS, ZnO/MgO, or the like.

Here, blue light is light having a central emission wavelength in the wavelength band of 400 nm or more to 500 nm or less. Furthermore, green light is light having a central emission wavelength in the wavelength band of greater than 500 to 600 nm or less. Furthermore, red light is light having a central emission wavelength in the wavelength band of greater than 600 to 780 nm or less.

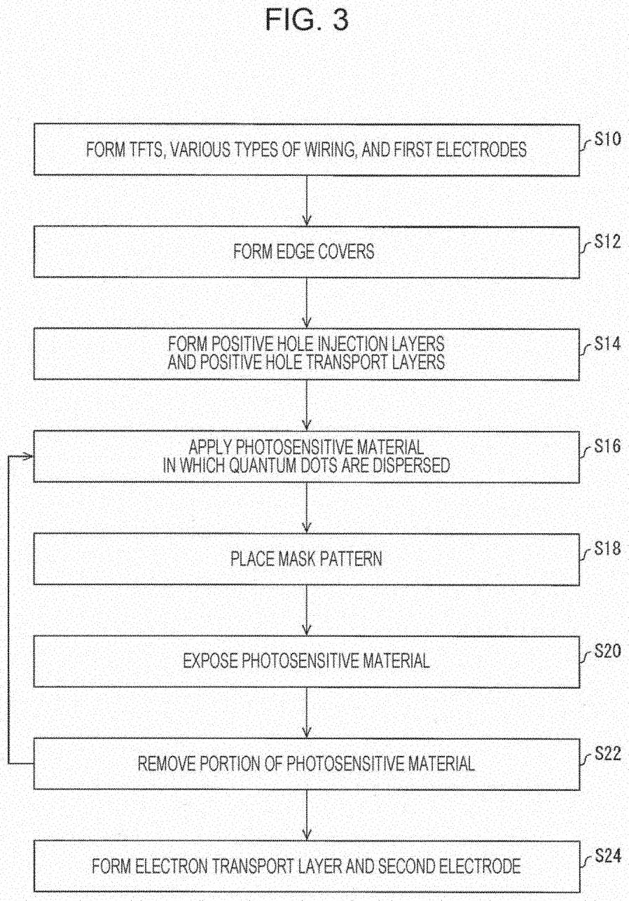

Next, a manufacturing method for the light-emitting device 2 according to the present embodiment will be described with reference to FIGS. 1 and 3. FIG. 1 is a cross-sectional view of steps for describing the manufacturing method for the light-emitting device 2. FIG. 3 is a flowchart of the manufacturing method for the light-emitting device 2 according to the present embodiment.

First, the TFTs and the array substrate 4 provided with various types of wiring connected to the TFTs are made, and the first electrodes 8a, which are electrically connected to the TFTs, are formed on the array substrate 4 (S10). Next, the edge covers 6 are formed between the first electrodes 8a (S12). The positive hole injection layers 10 and the positive hole transport layers 12 are formed in this order from the downward side as layers above the first electrodes 8a (S14), and the structure depicted in FIG. 1(a) is obtained. Conventional publicly-known methods may be employed, as appropriate, as methods for manufacturing the elements up to this point.

Next, a manufacturing method for the light-emitting layers 14 will be described. The light-emitting layers 14 according to the present embodiment are made using photolithography, from a photosensitive material in which quantum dots are dispersed. First, as depicted in FIG. 1(b), a photosensitive material 14a in which red quantum dots RD are dispersed is applied onto the positive hole transport layers 12 which constitute a base material (S16). The application of the photosensitive material 14a may be carried out using a publicly-known method such as a spin coating method, spray coating, a casting method, a printing method including an ink jet method, or an LB method, for example. The thickness of the photosensitive material 14a is preferably 10 nm or more, and more preferably 20 nm or more, from the viewpoint of ensuring a film thickness with which application and patterning can be easily controlled.

Furthermore, the thickness of the photosensitive material 14a is preferably 500 nm or less, and more preferably less than 200 nm, from the viewpoint of facilitating carrier injection and improving light emission efficiency.

The photosensitive material 14a may include a photosensitive resin such as SU-8 (Nippon Kayaku), KI Series (Hitachi Chemical), AZ Photoresist (Merck), or SUMIRESIST (Sumitomo Chemical), for example. Furthermore, the photosensitive material 14a contains at least one of a photopolymerization initiator and a photoacid generator. It is sufficient for the concentration of the quantum dots with respect to the photosensitive material 14a to be selected, as appropriate, so that the application thereof is easy and a desired film thickness can be obtained. Specifically, the concentration of the quantum dots with respect to the photosensitive material 14a is preferably in the range of 1 to 50 wt %, and more preferably in the range of 10 to 40 wt %. If less than the aforementioned concentration, the desired light emission performance cannot be sufficiently obtained and the light-emitting layers of the light-emitting device cannot be formed. Furthermore, if the aforementioned ranges are exceeded, the quantum dot components increase, and thus the stability of the formed film is impaired and there is a possibility of deterioration in flatness and patterning accuracy.

Next, as depicted in FIG. 1(c), a mask pattern M is placed above the photosensitive material 14a (S18), and light is radiated from above the mask pattern M and the photosensitive material 14a is exposed (S20). In other words, in the photosensitive material 14a, an exposed region is formed in a location where the mask pattern M is not present thereabove, and an unexposed region is formed in a location where the mask pattern M is present thereabove. For the light when exposure is carried out, i-rays (wavelength 365 nm) may be employed, for example; however, the light during exposure may be selected, as appropriate, according to materials. Furthermore, the exposure quantity is preferably 20 mJ/cm² or more from the viewpoint of improving pattern accuracy and reducing film thinning. Furthermore, the exposure quantity is preferably 1000 mJ/cm² or less from the viewpoint of suppressing a takt increase and reducing damage to other members.

At such time, the mask pattern M is placed above the green pixel region GP, the blue pixel region BP, and the edge covers 6. Therefore, the light radiated onto the green pixel region GP, the blue pixel region BP, and the edge covers 6 becomes an unexposed region that is shielded by the mask pattern M. Consequently, only the photosensitive material 14a on the positive hole transport layer 12 formed in the red pixel region RP is exposed and becomes an exposed region. The photosensitive material 14a in the exposed region alters and becomes a light-emitting layer 14.

Next, the photosensitive material 14a is cleaned with a developing solution, and the photosensitive material 14a is removed (S22). The developing solution is TMAH, for example; however, it is sufficient for the developing solution to be selected, as appropriate, according to the photosensitive material 14a. Here, the photosensitive material 14a is a negative photosensitive material, which acquires poor solubility with respect to the developing solution due to being exposed. Therefore, as depicted in FIG. 1(d), only the light-emitting layer 14 constituted by the exposed photosensitive material 14a is not dissolved in the developing solution and remains on the positive hole transport layers 12. Therefore, the light-emitting layer 14 having the red quantum dots RD is formed only in the red pixel region RP.

The aforementioned steps S16, S18, S20, and S22 are repeated, a light-emitting layer 14 having green quantum dots GD is formed in the green pixel region GP, and a light-emitting layer 14 having blue quantum dots BD is formed in the blue pixel region BP. The structure depicted in FIG. 1(e) is thereby obtained. Lastly, the electron transport layer 16 and the second electrode 18a are formed in this order from the downward side as layers above the light-emitting layers 14 (S24). The formation of the electron transport layer 16 and the second electrode 18a may be carried out using a sputtering method, a vacuum deposition method, or the like other than the aforementioned printing method.

According to the above, the light-emitting device 2 depicted in FIG. 1(f) is manufactured. It should be noted that, in the aforementioned manufacturing steps for the light-emitting device 2, in practice, after the application of the photosensitive material 14a, prebaking may be carried out to remove solvent from the photosensitive material 14a. Furthermore, after development of the light-emitting layers 14, postbaking may be carried out to ensure the adhesion with the base material and improve the resistance to the processing in the subsequent steps, of the light-emitting layers 14.

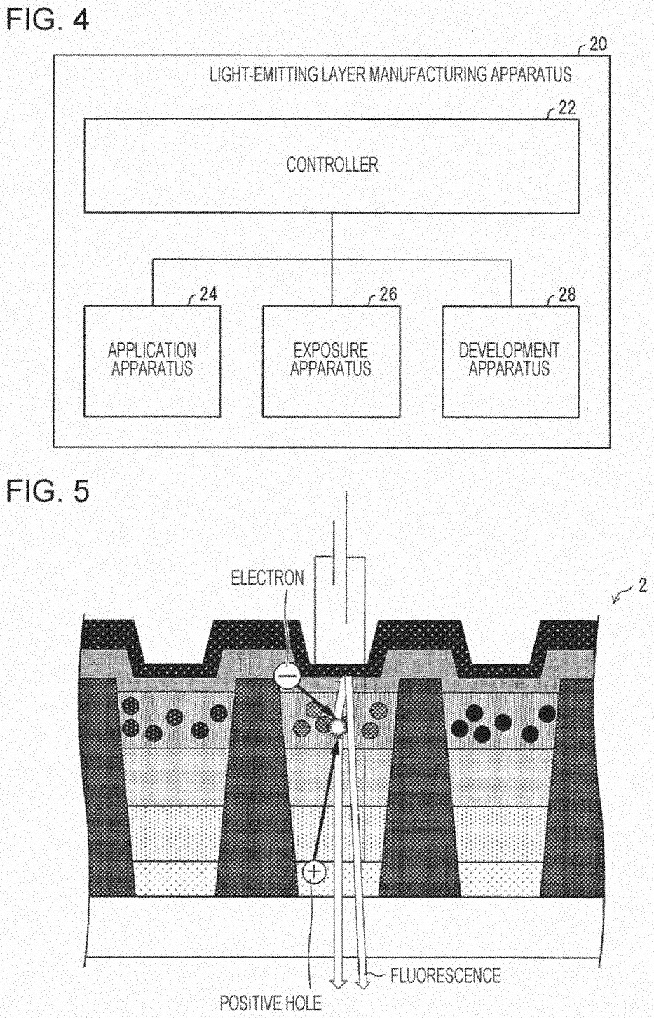

FIG. 4 is a block diagram depicting a light-emitting layer manufacturing apparatus 20, which is used when manufacturing the light-emitting layers 14 in the aforementioned manufacturing steps for the light-emitting device 2. The light-emitting layer manufacturing apparatus 20 is provided with a controller 22, an application apparatus 24, an exposure apparatus 26, and a development apparatus 28. The application apparatus 24 carries out the application of a photosensitive material 24a in which quantum dots are dispersed, onto a base material. The exposure apparatus 26 places the mask pattern M above the photosensitive material 24a on the base material, and radiates light onto at least a portion of the photosensitive material 24a. After light has been radiated onto the photosensitive material 24a, the development apparatus 28 removes at least a portion of the photosensitive material 24a. The controller 22 controls the application apparatus 24, the exposure apparatus 26, and the development apparatus 28.

In the aforementioned manufacturing method, there are no high-temperature processes within the formation or after the formation of the light-emitting layers having quantum dots. It is therefore possible to reduce the possibility of the light-emitting performance of the quantum dots being deactivated and fluorescence no longer being generated. Consequently, according to the aforementioned manufacturing method, there is an improvement in the yield in the manufacturing of the light-emitting device 2. Furthermore, in the aforementioned manufacturing method, the light-emitting layers 14 can be formed using photolithography. It is therefore possible for the light-emitting layers 14 to be formed with good patterning accuracy and with an increase in the takt time being suppressed. Consequently, the aforementioned manufacturing method makes it easier to increase the size and increase the resolution of the light-emitting device 2, and is therefore more suitable for mass production.

Furthermore, in the aforementioned manufacturing method, quantum dots are dispersed inside the photosensitive material 14a and the light-emitting layers 14. Therefore, when the light-emitting layers 14 are formed or in a step after the light-emitting layers 14 have been formed, it is possible to reduce the quantum dots coming into direct contact with oxygen, moisture, or the like and to reduce damage to the quantum dots. Therefore, according to the aforementioned manufacturing method, there is a further improvement in the yield in the manufacturing of the light-emitting device 2.

FIG. 5 is a cross-sectional view describing the light emission mechanism of the light-emitting device 2 according to the present embodiment. FIG. 5 depicts the case where fluorescence is generated from the green quantum dots GD of the light-emitting device 2.

First, as depicted in FIG. 5, a voltage is applied between the two electrodes in the green pixel region GP. Specifically, a voltage is applied between the two electrodes of the first electrode 8a (pixel electrode) corresponding to the green pixel region GP and the opposing second electrode 18a by controlling the TFT on the array substrate 4. A potential difference is generated so that the first electrode 8a which is an anode has a higher potential than the second electrode 18a which is a cathode. Thus, positive holes are injected from the first electrode 8a and the positive hole injection layer 10 to the positive hole transport layer 12, and electrons are injected from the second electrode 18a to the electron transport layer 16. Positive holes and electrons are transported to the light-emitting layer 14 by the positive hole transport layer 12 and the electron transport layer 16 respectively. Then, in the green quantum dots GD within the light-emitting layer 14, the positive holes and the electrons recombine, thereby generating excitons. When these excitons transition to a ground state, green fluorescence is generated in the green quantum dots GD.

Of the fluorescence generated in the green quantum dots GD, the fluorescence generated downward passes through the first electrode 8a which is a transparent electrode and the array substrate 4 which is a transparent substrate, and is radiated below the light-emitting device 2. Meanwhile, of the fluorescence generated in the green quantum dots GD, the fluorescence generated upward is reflected at the second electrode 18a which is a reflection electrode. Therefore, this fluorescence is also radiated below the light-emitting device 2. The fluorescence generated in the green quantum dots GD is all radiated below, and therefore the light emission efficiency improves. The aforementioned light emission mechanism is the same also for fluorescence generated in the red pixel region RP and the blue pixel region BP.

### Embodiment 2

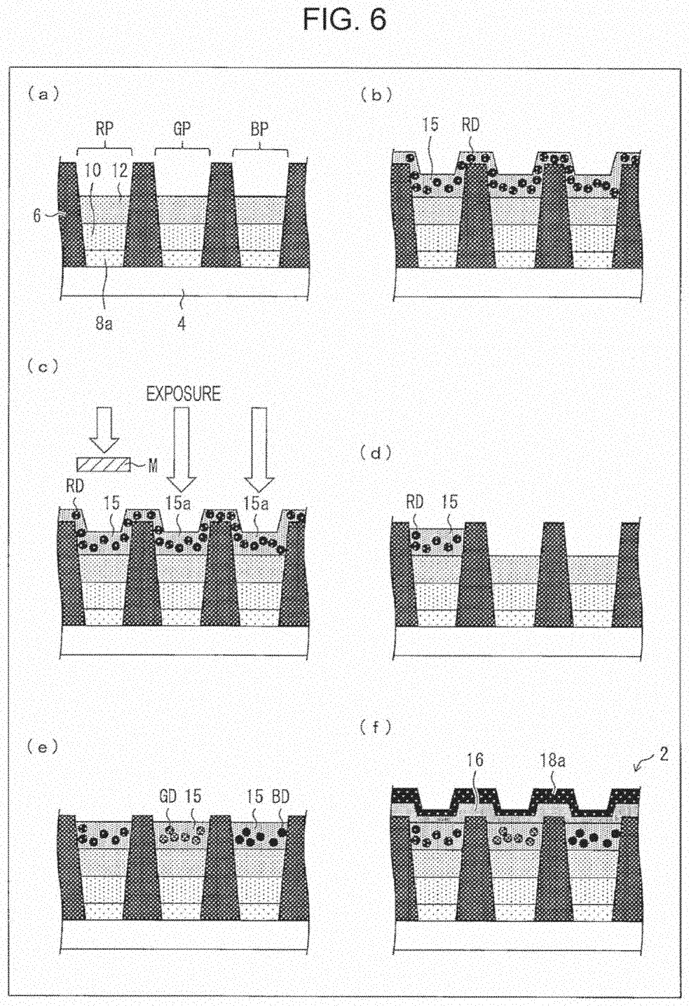

FIG. 6 is a cross-sectional view of steps depicting another example of a manufacturing method for a light-emitting device 2 according to the present embodiment. The light-emitting device 2 according to the present embodiment is different from the light-emitting device 2 according to the aforementioned embodiment only in being provided with light-emitting layers 15 including a positive photosensitive material, instead of the light-emitting layers 14. The manufacturing method for the light-emitting device 2 according to the present embodiment will be described with reference to FIGS. 3 and 6.

First, similar to the aforementioned manufacturing method for the light-emitting device 2, an array substrate is made with first electrodes 8a electrically connected to TFTs being formed thereon, and edge covers 6 are formed between electrodes. Positive hole injection layers 10 and positive hole transport layers 12 are formed as layers above the first electrodes 8a (S10, S12, and S14), and the structure depicted in FIG. 6(a) is obtained. Next, as depicted in FIG. 6(b), a positive photosensitive material in which red quantum dots RD are dispersed is applied onto the positive hole transport layers 12 which constitute a base material (S16), prebaking or the like is used to solidify the photosensitive material, and a light-emitting layer 15 is thereby obtained.

Next, as depicted in FIG. 6(c), a mask pattern M is placed above only the red pixel region RP (S18), and light is radiated from above the light-emitting layer 15 and the light-emitting layer 15 is exposed (S20). The light-emitting layer 15, due to being exposed, alters to an exposed light-emitting layer 15a having improved solubility with respect to a developing solution. Therefore, by cleaning the light-emitting layer 15 and the exposed light-emitting layer 15a using the developing solution, the exposed light-emitting layer 15a is removed (S22). Therefore, the light-emitting layer 15 having the red quantum dots RD is formed only in the red pixel region RP.

The aforementioned steps S16, S18, S20, and S22 are repeated, a light-emitting layer 15 having green quantum dots GD is formed in the green pixel region GP, and a light-emitting layer 15 having blue quantum dots BD is formed in the blue pixel region BP. The structure depicted in FIG. 6(e) is thereby obtained. Lastly, an electron transport layer 16 and a second electrode 18a are formed in this order from the downward side as layers above the light-emitting layers 14 (S24). According to the above, the light-emitting device 2 depicted in FIG. 6(f) is manufactured.

In the manufacturing method for the light-emitting device 2 according to the present embodiment, when the light-emitting layers 15 are formed, the exposed light-emitting layers 15a are removed and the unexposed light-emitting layers 15 remain. In other words, the light-emitting device 2 is provided with unexposed light-emitting layers 15. Consequently, the quantum dots provided in the light-emitting layers 15 are not irradiated with light when exposure is carried out, and therefore there is a reduction in the possibility of the quantum dots being damaged when exposure is carried out. Therefore, according to the aforementioned manufacturing method, there is a further improvement in the yield in the manufacturing of the light-emitting device 2. It should be noted that the light emission mechanism of the light-emitting device 2 according to the present embodiment may be the same as the light emission mechanism of the light-emitting device 2 according to the aforementioned embodiment.

### Embodiment 3

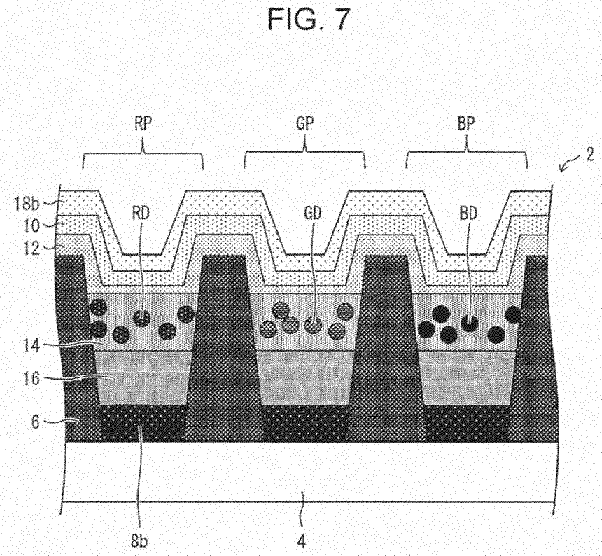

FIG. 7 is a cross-sectional view depicting a light-emitting device 2 according to the present embodiment. The light-emitting device 2 according to the present embodiment is provided with first electrodes 8b instead of the first electrodes 8a and a second electrode 18b instead of the second electrode 18a.

The light-emitting device 2 according to the present embodiment is provided with the first electrodes 8b, electron transport layers 16, and light-emitting layers 14 in this order from the downward side, in each pixel region surrounded by edge covers 6 on an array substrate 4. The first electrodes 8b are cathodes and have light-reflecting properties. The first electrodes 8b may include the same material as the material included in the second electrode 18a.

A positive hole transport layer 12, a positive hole injection layer 10, and the second electrode 18b are formed in this order from the downward side as layers above the light-emitting layers 14. The second electrode 18b is an anode and has light-transmitting properties. The second electrode 18b may include the same material as the material included in the first electrodes 8a.

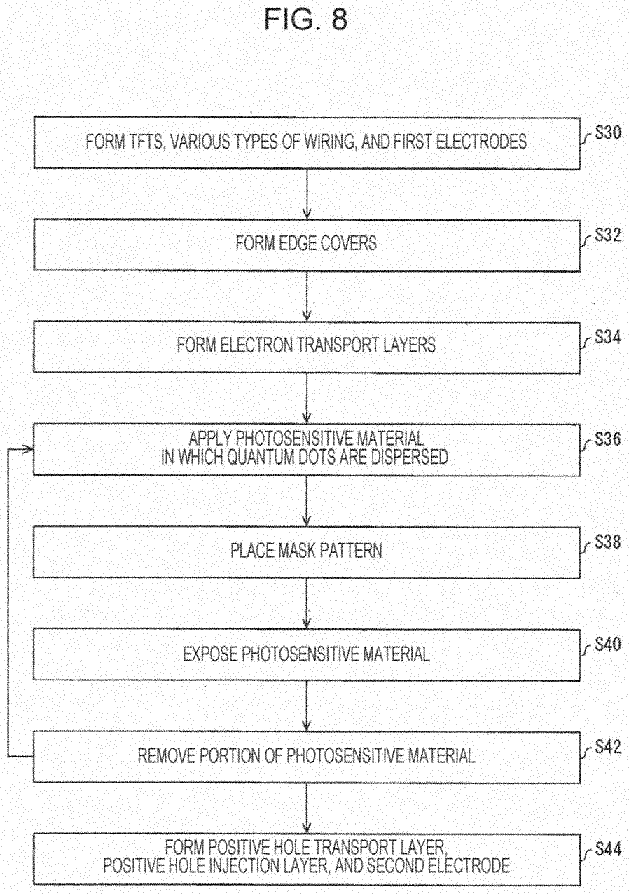

Next, a manufacturing method for the light-emitting device 2 according to the present embodiment will be described with reference to FIG. 8. FIG. 8 is a flowchart of the manufacturing method for the light-emitting device 2 according to the present embodiment.

First, similar to the aforementioned manufacturing method for the light-emitting device 2, TFTs and the array substrate 4 provided with various types of wiring connected to the TFTs are made, and the first electrodes 8b, which are electrically connected to the TFTs, are formed on the array substrate 4. Next, the edge covers 6 are formed between the first electrodes 8b. Next, electron injection layers 16 are formed in this order from the downward side as layers above the first electrodes 8b (S34).

Next, a light-emitting layer 14 is formed in the red pixel region RP. The formation of the light-emitting layer 14 may be carried out by means of the same method as that for the aforementioned formation of the light-emitting layers 14. In other words, a photosensitive material 14a may be applied onto an electron injection layer (S36), a mask pattern M may be placed (S38), the photosensitive material 14a may be exposed (S40), and a portion of the photosensitive material 14a may be removed (S42). A light-emitting layer 14 in which red quantum dots RD are dispersed is thereby formed in the red pixel region RP. Similarly, the steps S36, S38, S40, and S42 may be repeated also in the green pixel region GP and the blue pixel region BP to form light-emitting layers 14 in which green quantum dots GD and blue quantum dots BD are respectively dispersed.

Lastly, similar to the aforementioned manufacturing method for the light-emitting device 2, the positive hole transport layer 12, the positive hole injection layer 10, and the second electrode 18b are formed in this order from the downward side as layers above the light-emitting layers 14 (S44). The light-emitting device 2 according to the present embodiment is thereby obtained.

In the aforementioned manufacturing method for the light-emitting device 2, the light-emitting layers 14 provided with quantum dots are not present when the electron injection layers 16 are formed. Therefore, in the formation of the electron injection layers 16, there is no damage to the quantum dots even if a high-temperature process is applied.

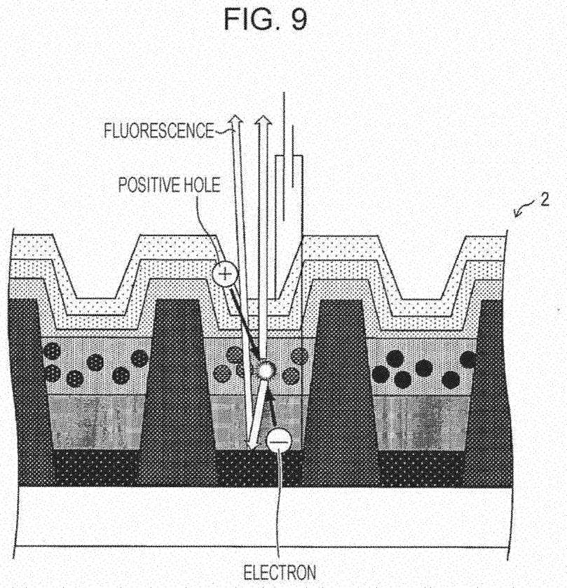

FIG. 9 is a cross-sectional view describing the light emission mechanism of the light-emitting device 2 according to the present embodiment. Similar to FIG. 5, FIG. 9 also depicts a case where fluorescence is generated from the green quantum dots GD of the light-emitting device 2.

First, as depicted in FIG. 9, a voltage is applied between the two electrodes in the green pixel region GP. Specifically, a voltage is applied between the two electrodes of the first electrode 8b (pixel electrode) corresponding to the green pixel region GP and the opposing second electrode 18b by controlling the TFT on the array substrate 4. A potential difference is generated so that the first electrode 8b which is a cathode has a lower potential than the second electrode 18b which is an anode. Thus, electrons are injected from the first electrode 8b to the electron transport layer 16, and positive holes are injected from the second electrode 18b and the positive hole injection layer 10 to the positive hole transport layer 12. The fluorescence generation mechanism in the light-emitting layer 14 thereafter is the same as the mechanism described with reference to FIG. 5.

Of the fluorescence generated in the green quantum dots GD, the fluorescence generated upward passes through the positive hole transport layer 12 and the positive hole injection layer 10 which are transparent thin films and the second electrode 18b which is a transparent electrode, and is radiated above the light-emitting device 2. Meanwhile, of the fluorescence generated in the green quantum dots GD, the fluorescence generated downward is reflected at the first electrode 8b which is a reflection electrode. Therefore, this fluorescence is also radiated above the light-emitting device 2. The fluorescence generated in the green quantum dots GD is all radiated above, and therefore the light emission efficiency improves.

Furthermore, in the light-emitting device 2 according to the present embodiment, the direction in which fluorescence is produced is above the light-emitting device 2 where the TFTs are not formed. It is therefore possible to further widen the openings through which the fluorescence radiated from the light-emitting layers 14 passes. Consequently, the light-emitting device 2 according to the present embodiment is able to further increase light emission efficiency.

### Embodiment 4

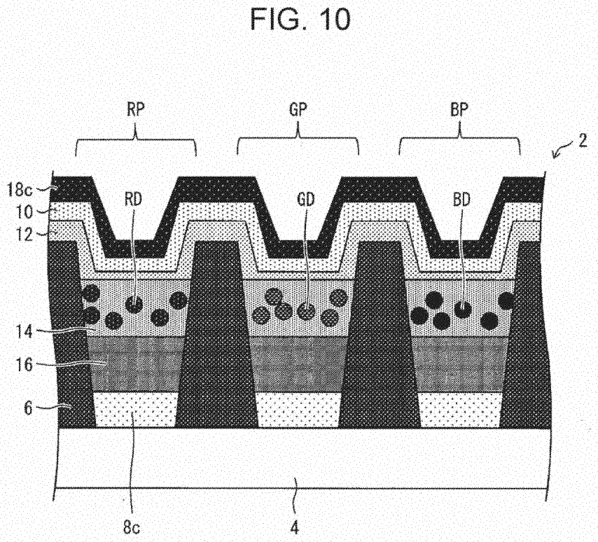

FIG. 10 is a cross-sectional view depicting a light-emitting device 2 according to the present embodiment. The light-emitting device 2 according to the present embodiment is different from the light-emitting devices 2 according to the aforementioned embodiments only in being provided with first electrodes 8c instead of the first electrodes 8b and a second electrode 18c instead of the second electrode 18b.

The first electrodes 8c are cathodes and have light-transmitting properties. The first electrodes 8c may include the same material as the material included in the first electrodes 8a. The second electrode 18c is an anode and has light-reflecting properties. The second electrode 18c may include the same material as the material included in the second electrode 18a.

The light-emitting device 2 according to the present embodiment is different from the light-emitting devices 2 according to the aforementioned embodiments only in that the materials used and the electrode properties are reversed in the first electrodes and the second electrodes. Therefore, the light-emitting device 2 according to the present embodiment can be manufactured by means of the same manufacturing methods as those of the light-emitting devices 2 according to the aforementioned embodiments. Consequently, in the present embodiment also, in the formation of the electron injection layer 16, there is no damage to the quantum dots even if a high-temperature process is applied.

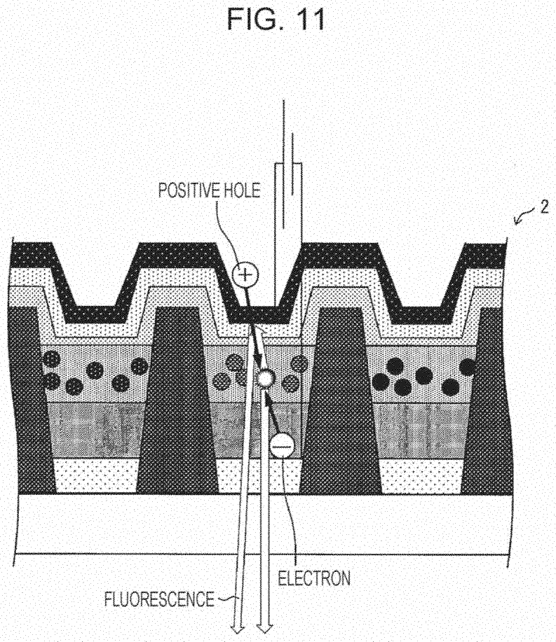

FIG. 11 is a cross-sectional view describing the light emission mechanism of the light-emitting device 2 according to the present embodiment. Similar to FIGS. 5 and 9, FIG. 11 also depicts the case where fluorescence is generated from the green quantum dots GD of the light-emitting device 2. The mechanism for generating fluorescence from the light-emitting layers of the light-emitting device 2 according to the present embodiment is the same as the mechanism described with reference to FIG. 9. Furthermore, as described with reference to FIG. 5, in the light-emitting device 2 according to the present embodiment also, fluorescence is radiated below the light-emitting device 2. The fluorescence generated in the green quantum dots GD is all radiated below, and therefore the light emission efficiency improves.

### SUMMARY

A light-emitting layer of aspect 1 is formed of a photosensitive material, in which quantum dots are dispersed.

In aspect 2, there are at least three types of the quantum dots, in which wavelength bands of fluorescence are respectively different.

In aspect 3, a thickness is 10 nm or more to 500 nm or less.

In aspect 4, at least one of a photopolymerization initiator and a photoacid generator is included.

In aspect 5, the photosensitive material is a negative photosensitive material.

In aspect 6, the photosensitive material is a positive photosensitive material.

A light-emitting device of aspect 7 is provided with the light-emitting layer, a first electrode of a lower layer than the light-emitting layer, and a second electrode of a higher layer than the light-emitting layer.

In aspect 8, the light-emitting layer is divided into a plurality of pixel regions.

In aspect 9, the quantum dots in the light-emitting layer provided in a portion of the pixel regions are different from the quantum dots in the light-emitting layer provided in the other different pixel regions.

In aspect 10, at least one of the first electrode and the second electrode has light-transmitting properties.

In aspect 11, the first electrode has light-reflecting properties.

In aspect 12, the second electrode has light-reflecting properties.

In aspect 13, the first electrode is an anode and the second electrode is a cathode.

In aspect 14, the first electrode is a cathode and the second electrode is an anode.

A light-emitting layer manufacturing apparatus of aspect 15 carries out: application of a photosensitive material in which quantum dots are dispersed, onto a base material; formation of an exposed region and an unexposed region in the photosensitive material on the base material; and removal of the photosensitive material in at least a portion of the exposed region or at least a portion of the unexposed region.

A manufacturing method for a light-emitting layer of aspect 16 includes: an application step in which a photosensitive material in which quantum dots are dispersed is applied onto a base material; an exposure step in which an exposed region and an unexposed region are formed in the photosensitive material on the base material; and a development step in which the photosensitive material is removed in at least a portion of the exposed region or at least a portion of the unexposed region after the exposure step.

In aspect 17, the photosensitive material includes at least one of a photopolymerization initiator and a photoacid generator.

A manufacturing method for a light-emitting device of aspect 18 includes the manufacturing method for the light-emitting layer.

In aspect 19, an edge cover formation step is also included, in which edge covers that divide the photosensitive material into a plurality of pixel regions are formed.

In aspect 20, a light-emitting layer is formed in a portion of the pixel regions, the light-emitting layer having quantum dots of a different type from quantum dots in light-emitting layers formed in other different pixel regions.

In aspect 21, there are also included a first electrode formation step in which a first electrode of a lower layer than the photosensitive material is formed, and a second electrode formation step in which a second electrode of a higher layer than the photosensitive material is formed.

In aspect 22, of the photosensitive material, the photosensitive material in at least a portion of the exposed region is removed in the development step.

In aspect 23, of the photosensitive material, the photosensitive material in at least a portion of the unexposed region is removed in the development step.

In aspect 24, in the exposure step, a mask pattern is placed above the photosensitive material, and the exposed region and the unexposed region are formed.

The present invention is not restricted to the aforementioned embodiments, various alterations are possible within the scope indicated in the claims, and embodiments obtained by appropriately combining the technical means disclosed in each of the different embodiments are also included within the technical scope of the present invention. In addition, novel technical features can be formed by combining the technical means disclosed in each of the embodiments.

### REFERENCE SIGNS LIST

2 Light-emitting device
6 Bank layer
8a to 8c First electrode
14, 15 Light-emitting layer
18a to 18c Second electrode
20 Light-emitting layer manufacturing apparatus
RP, GP, BP Pixel region
RD, GD, BD Quantum dots
M Mask pattern

1. A light-emitting layer formed of a photosensitive material, in which quantum dots are dispersed.

2. The light-emitting layer according to claim 1, having at least three types of the quantum dots, in which wavelength bands of fluorescence are respectively different.

3. The light-emitting layer according to claim 1, wherein a thickness is 10 nm or more to 500 nm or less.

4. The light-emitting layer according to claim 1, comprising at least one of a photopolymerization initiator and a photoacid generator.

5. The light-emitting layer according to claim 1, comprising a negative photosensitive material.

6. The light-emitting layer according to claim 1, comprising a positive photosensitive material.

7. A light-emitting device comprising the light-emitting layer according to claim 1, a first electrode of a lower layer than the light-emitting layer, and a second electrode of a higher layer than the light-emitting layer.

8. The light-emitting device according to claim 7, wherein the light-emitting layer is divided into a plurality of pixel regions.

9. The light-emitting device according to claim 8, wherein the quantum dots in the light-emitting layer provided in a portion of the pixel regions are different from the quantum dots in the light-emitting layer provided in other different pixel regions.

10. The light-emitting device according to claim 7, wherein at least one of the first electrode and the second electrode has light-transmitting properties.

11. The light-emitting device according to claim 7, wherein the first electrode has light-reflecting properties.

12. The light-emitting device according to claim 7, wherein the second electrode has light-reflecting properties.

13. The light-emitting device according to claim 7, wherein the first electrode is an anode and the second electrode is a cathode.

14. The light-emitting device according to claim 7, wherein the first electrode is a cathode and the second electrode is an anode.

15. A light-emitting layer manufacturing apparatus carries out:
application of a photosensitive material in which quantum dots are dispersed, onto a base material;
formation of an exposed region and an unexposed region in the photosensitive material on the base material; and
removal of the photosensitive material in at least a portion of the exposed region or at least a portion of the unexposed region.
